(19) United States
(12) Patent Application Publication
(10) Pub. No.: US 2024/0128181 A1
(43) Pub. Date: Apr. 18, 2024

(54) PACKAGE SUBSTRATE WITH DUAL DAMASCENE BASED SELF-ALIGNED VIAS

(71) Applicant: Intel Corporation, Santa Clara, CA (US)

(72) Inventors: Jeremy Ecton, Gilbert, AZ (US); Brandon C. Marin, Gilbert, AZ (US); Srinivas V. Pietambaram, Chandler, AZ (US); Hiroki Tanaka, Gilbert, AZ (US); Haobo Chen, Chandler, AZ (US)

(73) Assignee: Intel Corporation, Santa Clara, CA (US)

(21) Appl. No.: 18/047,033

(22) Filed: Oct. 17, 2022

(51) Int. Cl. H01L 23/498; H01L 21/48; H01L 23/14; H01L 23/538; H01L 25/065

(52) U.S. Cl. CPC H01L 23/49838; H01L 21/4857; H01L 21/486; H01L 23/145; H01L 23/49822; H01L 23/5381; H01L 23/5383; H01L 23/5386; H01L 25/0655; H01L 24/32; H01L 2924/15311

(57) ABSTRACT

Embodiments of a microelectronic assembly that includes: a package substrate comprising a plurality of layers of organic dielectric material and conductive traces alternating with conductive vias in alternate layers of the organic dielectric material; and a plurality of integrated circuit dies coupled to a first side of the package substrate by interconnects, in which: the plurality of layers of the organic dielectric material comprises at least a first layer having a conductive via and a second layer having a conductive trace in contact with the conductive via, the second layer is not coplanar with the first layer, sidewalls of the conductive via are orthogonal to the conductive trace, and two opposing sidewalls of the conductive via separated by a width of the conductive via protrude from respectively proximate edges of the conductive trace by a protrusion that is at least ten times less than the width of the conductive via.

### TECHNICAL FIELD

The present disclosure relates to techniques, methods, and apparatus directed to a package substrate with dual damascene based self-aligned vias.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2A is a schematic plan view of a portion of a microelectronic assembly according to some embodiments of the present disclosure.

FIG. 2B is a schematic cross-sectional view of the portion of microelectronic assembly of FIG. 2A.

FIGS. 2C and 2D are schematic cross-sectional views of various details of the portion of FIG. 2B.

FIGS. 3A-3O are schematic cross-sectional and perspective views of a portion of a microelectronic assembly at various stages of manufacture according to some embodiments of the present disclosure.

FIG. 3P is a schematic plan view respectively of the portion of a microelectronic assembly of FIG. 3O.

FIG. 4 is a schematic cross-sectional view of a portion of a microelectronic assembly at one of many stages of manufacture according to some embodiments of the present disclosure.

FIGS. 5A-5H are schematic cross-sectional and perspective views of a portion of a microelectronic assembly at various stages of manufacture according to some embodiments of the present disclosure.

FIG. 7 is a cross-sectional view of a device package that includes one or more microelectronic assemblies in accordance with any of the embodiments disclosed herein.

FIG. 8 is a cross-sectional side view of a device assembly that includes one or more microelectronic assemblies in accordance with any of the embodiments disclosed herein.

FIG. 9 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

The demand for miniaturization of form factor and increased levels of integration for high performance are driving sophisticated packaging approaches in the semiconductor industry. Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets, tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout; this has different manufacturing requirements compared to a USB controller, which is built to meet certain USB standards, rather than for processing speed; by having different parts of the overall design separated into different dies, each one optimized in terms of design and manufacturing, the overall yield and cost of the combined die solution may be improved.

The connectivity between these dies is achievable by many ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. The bridge die may be embedded in an organic interposer, which allows for top-packaged chips to communicate with other chips horizontally using the bridge die and vertically, using Through-Mold Vias (TMVs) in the interposer. Such die partitioning enables miniaturization of small form factor and high performance without yield issues seen with other methods but needs fine die-to-die interconnections. The bridge die can facilitate such high-density interconnections by inserting the bridge dies only where needed. Standard flip-chip assembly is used for robust power delivery and to connect high-speed signals directly from chip to the package substrate.

For future generations of die partitioning, several bridges that can connect the dies at fine bump pitches (e.g., 25 microns or lower) than that are possible in current technologies are needed. In many packages with bridge dies, high cumulative Bump Thickness Variation (BTV) from the nature of organic dielectric materials used in the package substrate can make such fine bump pitches prohibitively expensive to manufacture due to low yields. In addition, connecting the bridge die to the overlying silicon dies through a stacked via configuration as is typical in current packages results in significant stresses at the via locations. The significant stresses on the vias can potentially result in a via crack, which is a significant reliability risk. By adopting a via staggering configuration wherein the vias are routed with an offset relative to the layer below and above a given patterning layer, the stresses can be significantly reduced as the staggering configuration acts as a cantilever to absorb stresses and reduce the likelihood of via cracking.

However, via staggering is ultimately limited by patterning resolution and overlay alignment error. Historically, there have been two key metrics driving lithography: on product overlay (also known as overlay alignment), and critical dimension uniformity. Both these metrics are monitored to reduce and eliminate edge placement error (EPE) (also called “overlay alignment error”). EPE is the difference between the intended and the printed features of a layout containing features, such as vias, in precise locations. Many variables feed into the EPE metric, including optical proximity correction, reticle manufacture errors, resist, expose, develop, on product overlay, critical dimension uniformity, line width roughness and post lithography processing such as etching.

Under such conventional lithography approaches, scaling from 25 micrometers bump pitch to 18 micrometers bump pitch pushes the via staggering design rules beyond existing capabilities of current lithography tools and materials. In particular, the overlay alignment error required to accommodate 25 micrometers bump pitch for a via diameter of 4 micrometers, for example, is less than 2 micrometers, with an additional 5 micrometers plane-to-plane patterning resolution to guarantee no overlap of vias (i.e., stacked via type configuration). Reducing the via diameter below 4 micrometers to alleviate the overlay alignment error is considered high risk to small via dimension and less resilient to stresses. Reducing the bump pitch further to 18 micrometers is considerably more challenging and would require a significant reduction in patterning resolution and/or overlay alignment error and/or via diameter to accommodate the tighter design rules, which is considered high risk in terms of process capability and/or via reliability.

In some techniques, via-pads are used to align vias onto conductive traces. Such via-pads are currently formed using registration of either laser drilling or a lithographic mask defining the via to existing fiducials on a layer of the substrate in which the via pad is disposed, i.e., the pad layer. However, due to shrinkage during curing of the dielectric layer deposited on the pad layer of the substrate and shifting the pad with respect to the fiducials, the via-to-pad registration is not preserved across the field of the substrate layer. The via-to-pad misalignment may cause device failures, decrease yield and increase manufacturing cost. Additionally, the large size of the pads and the reduced via registration capability limit the density of metal lines and other components on the substrate.

One possible solution to alleviate some of the overlay alignment error is to incorporate a zero-misaligned via process. A current technique for forming zero-misaligned vias incorporates a gray-scale exposure to create local differences in exposure dose, enabling separate develop and plate steps to create a zero-misaligned copper step or via. Yet, the process requires stringent control of dose, develop dwell time, and greyscale transmission. Additionally, such existing techniques for zero-misaligned or self-aligned vias result in an undesirable taper of the via sidewalls due to the isotropic nature of electrolytic plating. Such taper can impact the overlay budget (i.e., available space and dimensions for overlay), making smaller pitches difficult and expensive to achieve.

Accordingly, embodiments described herein enable a microelectronic assembly that includes: a package substrate comprising a plurality of layers of organic dielectric material and conductive traces alternating with conductive vias in alternate layers of the organic dielectric material; and a plurality of IC dies coupled to a first side of the package substrate by interconnects, in which: the plurality of layers of the organic dielectric material comprises at least a first layer having a conductive via and a second layer having a conductive trace in contact with the conductive via, the second layer is not coplanar with the first layer, sidewalls of the conductive via are orthogonal to the conductive trace, and two opposing sidewalls of the conductive via separated by a width of the conductive via protrudes from respectively proximate edges of the conductive trace by a protrusion that is at least ten times less than the width of the conductive via.

Some embodiments of a package substrate as disclosed herein comprises a plurality of layers of organic dielectric material; a conductive via in a first layer of the organic dielectric material; and a conductive trace in a second layer of the organic dielectric material. The second layer is over the first layer, the conductive via is attached to a portion of the conductive trace, and an EPE of the conductive via on the conductive trace is less than 0.1 micrometers.

Some embodiments of a package substrate comprise a plurality of layers of organic dielectric material; a conductive via in a first layer of the organic dielectric material; and a conductive trace in a second layer of the organic dielectric material. The first layer is over the second layer, the conductive via is attached to a portion of the conductive trace, at least one sidewall of the conductive via has a scalloped profile, and centerlines of the conductive via and the portion of the conductive trace are mutually aligned.

Embodiments disclosed herein further include a method, comprising: providing a support structure comprising a seed layer of conductive material over an organic dielectric material; depositing a first layer of photoresist over the seed layer; forming a first trench in the photoresist, the first trench corresponding to a portion of a conductive trace; depositing conductive material in the first trench; forming a second trench in the organic dielectric material, the second trend corresponding to a conductive via; depositing conductive material in the second trench to form the conductive trace and connected via; stripping any remaining photoresist and the seed layer; and depositing the organic dielectric material around and over the conductive trace.

Embodiments disclosed herein also include a method, comprising: providing a support structure comprising an organic dielectric material; depositing a layer of photoresist over the organic dielectric material; forming a trench in the organic dielectric material; depositing conductive material in the trench to form a conductive trace; wet etching the conductive trace to form a conductive via having at least one scalloped surface and scalloped edges along a periphery of the conductive trace; and depositing the organic dielectric material over the conductive trace.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O³, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

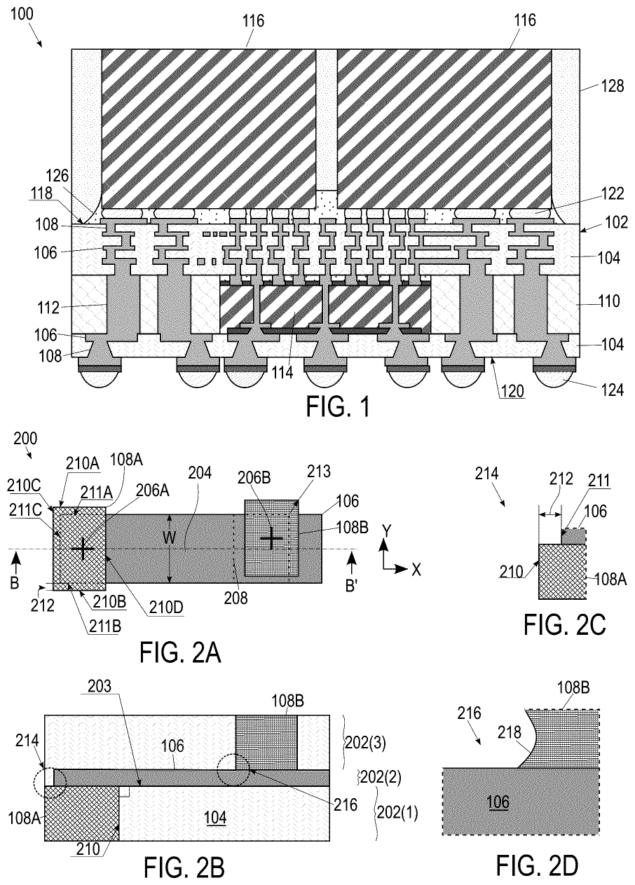

FIG. 1A is a schematic cross-sectional view of an example microelectronic assembly 100 according to some embodiments of the present disclosure. Microelectronic assembly 100 comprises a package substrate 102 comprising a plurality of layers of organic dielectric material 104 and conductive traces 106 alternating with conductive vias 108 in alternate layers of organic dielectric material 104. In some embodiments, organic dielectric material 104 comprises polyimide. In some other embodiments, organic dielectric material 104 comprises epoxy-based buildup film. In various embodiments, conductive vias 108 and conductive traces 106 comprise copper. In many embodiments, conductive vias 108 in alternating layers adjacent to a conductive trace 106 may be staggered with respect to each other (i.e., their centerlines are not aligned). In many embodiments, at least some conductive vias 108 and conductive traces 106 to which such vias 108 are attached may have zero-misalignment (i.e., they may be self-aligned). In some such embodiments, EPE of conductive via 108 relative to conductive trace 106 may be less than 0.1 micrometers. In some such embodiments, centerlines of such conductive vias 108 and conductive traces 106 may be mutually aligned. In various embodiments, sidewalls of conductive vias 108 may be orthogonal to conductive traces 106.

Package substrate 102 further comprises another organic dielectric material 110 through which conductive through-dielectric vias (TDVs) 112 are disposed. In some embodiments, organic dielectric material 110 comprises silica-filled epoxy, such as used in mold compounds. In some embodiments, organic dielectric materials 104 and 110 may comprise the same type of material (e.g., epoxy), or different materials (e.g., one is polyimide and the other is epoxy). In some embodiments, a bridge IC die 114 may be embedded in organic dielectric material 110. Bridge IC die 114 may comprise TSVs in some embodiments (e.g., as shown); in other embodiments, bridge IC die 114 may not comprise TSVs.

A plurality of IC dies 116 are coupled to a first surface 118 of the package substrate by interconnects 122. Package substrate 102 comprises a second surface 120 opposite first surface 118 on which are disposed interconnects 124. In some embodiments, interconnects 122 comprise FLIs and interconnects 124 comprise SLIs as discussed in the previous subsection. In some embodiments, organic dielectric material 104, along with conductive traces 106 and conductive vias 108 may be disposed proximate to second surface 120 of package substrate 102. In such embodiments, organic dielectric material 110 may be in between opposing regions of organic dielectric material 104.

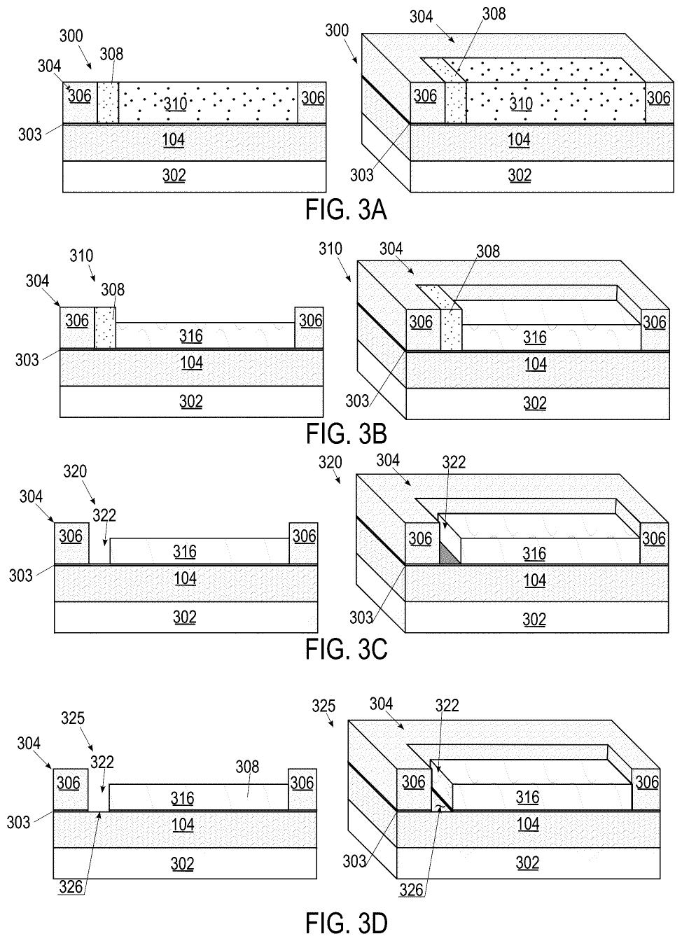

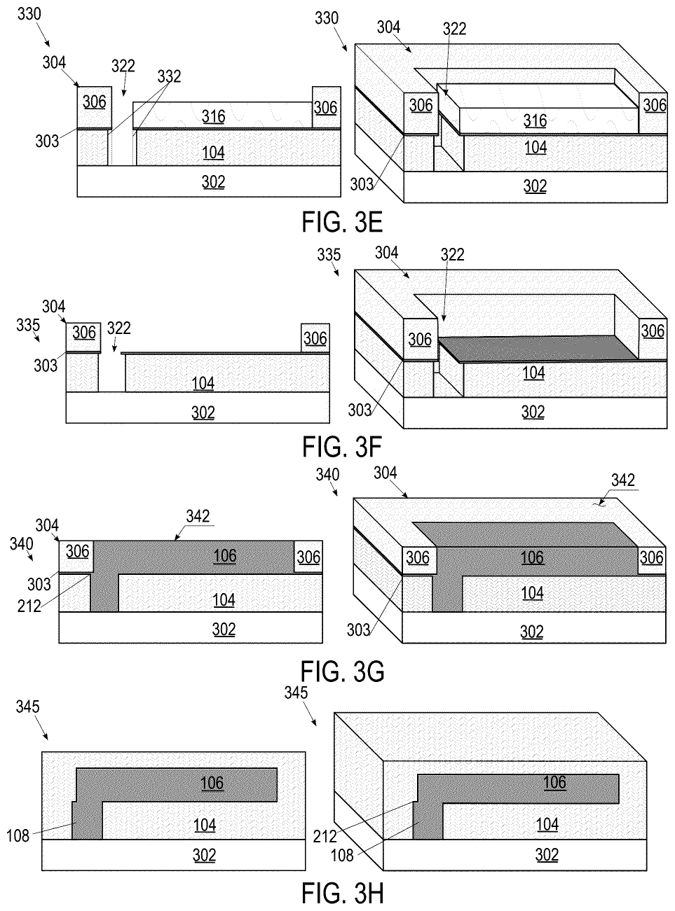

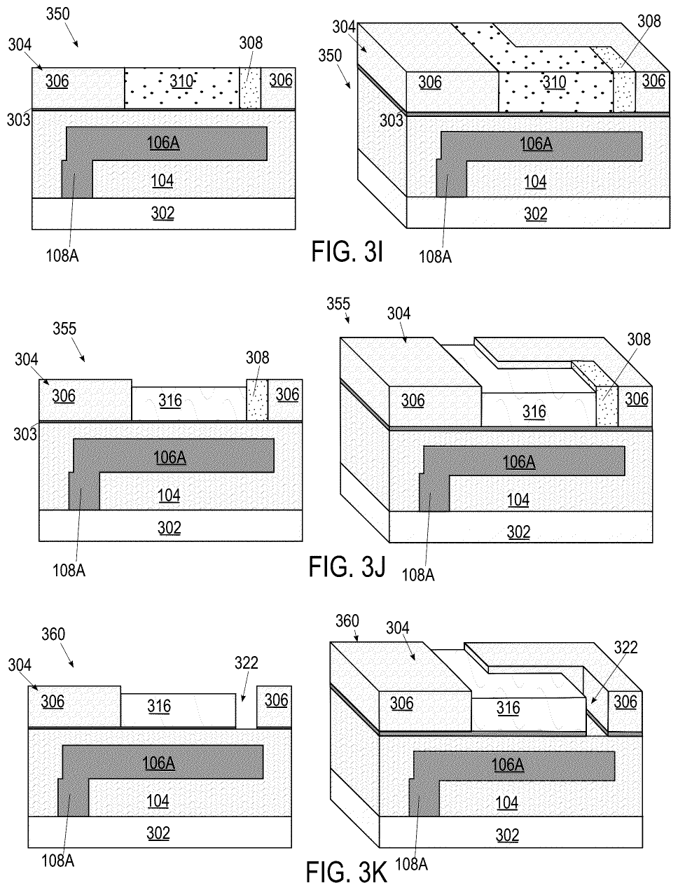

FIG. 2A shows a simplified cross-sectional view of a portion 200 of self-aligned conductive vias 108 and conductive traces 106 in organic dielectric material 104. A portion of conductive trace 106 coupled to staggered conductive vias 108 A and 108B may have a centerline 204. As shown in FIG. 2B, which is a simplified cross-sectional view of portion 200 of FIG. 2A, conductive vias 108A and 108B and conductive trace 106 are in separate layers 202 of organic dielectric material 104 that are not coplanar. Conductive via 108A is in layer 202(1) of organic dielectric material 104; conductive trace 106 is in layer 202(2) of organic dielectric material 104, and conductive via 108B is in layer 202(3) of organic dielectric material 104.

Conductive via 108A may have a center 206A and conductive via 108B may have a center 206B. Conductive vias 108A and 108B in alternating layers 202(1) and 202(3) adjacent to layer 202(2) of conductive trace 106 are staggered with respect to each other (e.g., along X-axis), i.e., they are not mutually aligned. Thus, centers 206A and 206B of respective conductive vias 108A and 108B are not vertically stacked one on top of another but may be displaced with respect to each other along layers 202.

In various embodiments, the spacing/pitch between adjacent conductive traces 106 or conductive vias 108 in the same layer 202 may be between approximately 1 micrometers and 3 micrometers. EPE 213 of conductive via 108A with respect to conductive trace 106 may be less than 0.1 micrometers. In some embodiments, conductive via 108B may be misaligned from its intended location 208 by an EPE 213 that is more than 0.1 micrometers, for example, in a range approximately between 0.1 micrometers and 1 micrometers. Thus, center 206A may be aligned with centerline 204 whereas center 206B may not be aligned with centerline 204. The misalignment of conductive via 108B may be along the Y-axis, orthogonal to centerline 204 of conductive trace 106 in some embodiments. In some embodiments, conductive via 108B may also be misaligned along the X-axis with respect to intended location 208. In some other embodiments, EPE 213 of conductive via 108B may be less than 0.1 micrometers.

The difference in misalignment of conductive vias 108A and 108B relative to conductive trace 106 may arise from the difference in photolithography processing used to fabricate conductive vias 108A and 108B. Whereas conductive via 108A may be formed by using a profile of conductive trace 106 as a hardmask to generate conductive via 108A thus resulting in zero-misalignment, conductive via 108B may be formed using another mask aligned by fiducials independent of conductive trace 106 and thus may be subject to traditional alignment errors.

Conductive via 108A may have sidewalls 210A, 210B, 210C and 210D. Sidewalls 210 may be orthogonal to conductive trace 106. Sidewalls 210A and 210B may be opposite each other, separated by a width of conductive via 108A. Sidewalls 210A and 210B may be proximate to surfaces 211A and 211B respectively of conductive trace 106. In various embodiments, sidewalls 210A and 210B may protrude from respective proximate surfaces 211A and 211B of conductive trace 106 by a protrusion 212 that is at least ten times less than the width of the conductive via 108B. The width of conductive via 108A is thus the sum of a width W of conductive trace 106 and twice protrusion 212. In embodiments where conductive via 108A is located at an edge of conductive trace 106, for example, proximate to surface 211C, sidewall 210C of conductive via 108A also protrudes from respectively proximate surface 211C of conductive trace 106 by protrusion 212. Protrusion 212 is shown in greater detail in FIG. 2C, which is a simplified cross-sectional view of portion 214 (see FIG. 2B) around an interface between conductive trace 106 and conductive via 108A. Sidewall 210 (which may be any one of sidewalls 210A, 210B or 210C) of conductive via 108A may protrude from surface 211 (which may be corresponding surfaces 211A, 211B or 211C) of conductive trace 106 by protrusion 212. In many embodiments, protrusion 212 may be less than an order of magnitude of the width of conductive via 108A.

Protrusion 212 is caused or occurs due to the processing method used to fabricate conductive via 108A. In various embodiments, dry etching with a plasma is used to remove organic dielectric material 104. Various types of plasma etchants are known in the art for semiconductor fabrication, such as reactive gases including fluorocarbons, oxygen, chlorine, boron trichloride, with (or without) addition of nitrogen, argon, helium and other gases. Any one of such types of plasma etchants may be used in various embodiments herein within the broad scope of the disclosure. Whereas in traditional semiconductor fabrication, dry etching is used to form recesses in materials such as silicon carbide or gallium nitride that are resistant to wet etchants, the technique is modified herein to be used on organic dielectric material 104 to generate a via profile that is suitable for zero-misaligned or self-aligned vias such as conductive vias 108 on conductive traces 106. The anisotropic etching characteristics of plasma-based dry etching can be advantageously applied to suitably remove organic dielectric material 104 according to desired patterns as described herein.

Although only one conductive via 108A is shown and described as being aligned with conductive trace 106, any number of such conductive vias 108A may be provisioned along the length of conductive trace 106, all of which are self-aligned with respect to conductive trace 106 within the broad scope of the embodiments herein. All such conductive vias 108A may be in a common layer 202(1) of organic dielectric material 104, adjacent to and under layer 202(2) in which conductive trace 106 is located.

In some embodiments, protrusion 212 may be absent; instead, as shown in FIG. 2D, which is a cross-sectional view of a detail 216 of portion 200 of FIG. 2B, a profile 218 of at least one of sidewalls 210 of conductive via 108 (e.g., 108B) may be scalloped (i.e., concave) and the other sidewalls 210 may be exactly in line with respectively proximate surfaces 211 of conductive trace 106. In some such embodiments, surfaces 211 of conductive trace 106 may have a scalloped profile as well. Such concave profiles arise from the wet etching process used to form conductive via 108. In such embodiments, conductive vias 108 with the scalloped sidewall profile 218 may be formed in layer 202(3) adjacent to and over layer 202(2) in which conductive trace 106 is located.

In various embodiments, any of the features discussed with reference to any of FIGS. 1-2 herein may be combined with any other features to form a package with one or more IC dies as described herein. For example, in some embodiments, all conductive vias 108 may be formed with protrusion 212 relative to conductive trace 106 as described for conductive via 108A in FIG. 2C. In some other embodiments, all conductive vias 108 may be formed with scalloped sidewalls 210 as described for conductive via 108B in FIG. 2D. In yet other embodiments, some conductive vias 108 may be formed with protrusion 212 relative to conductive trace 106 and some other conductive vias 108 may be formed with scalloped sidewalls 210, based on particular needs. Some such combinations are described above, but, in various embodiments, further combinations and modifications are possible. Various different embodiments described in different figures may be combined suitably based on particular needs within the broad scope of the embodiments.

### Example Methods

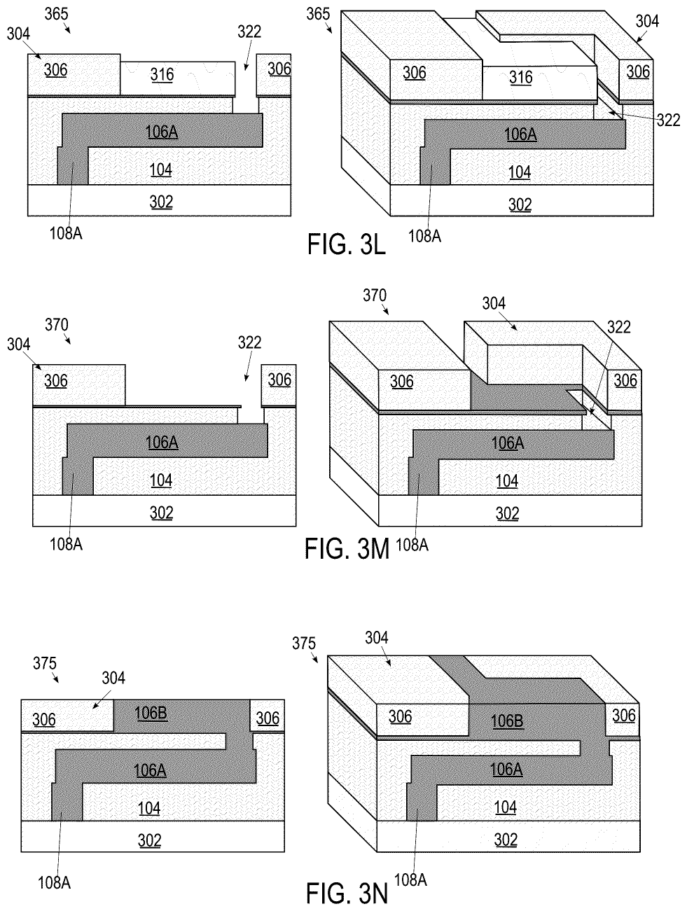

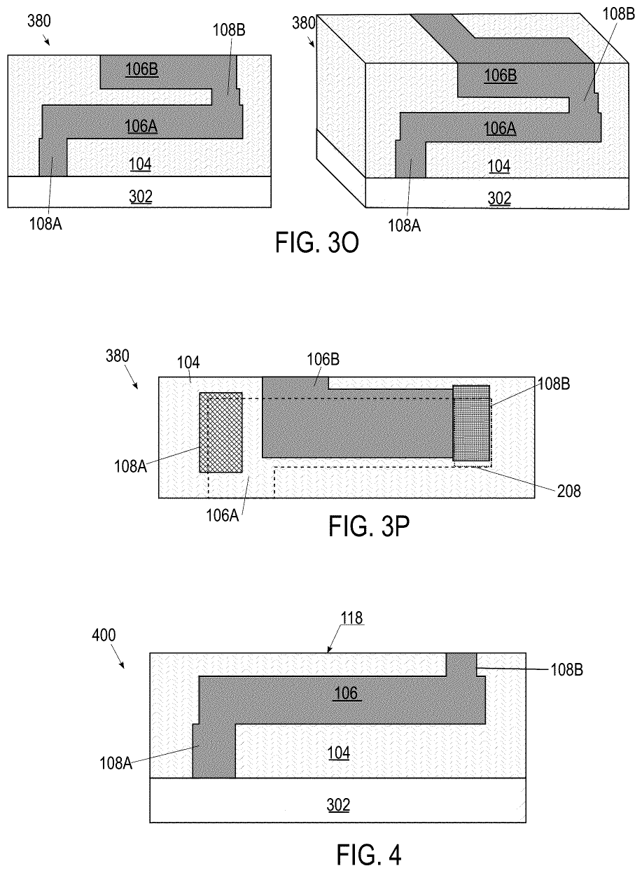

FIGS. 3A-3O are schematic cross-sectional views (left-hand side) and perspective views (right-hand side) of portions of microelectronic assembly 100 at various stages of manufacture according to some embodiments of the present disclosure. FIG. 3A shows a portion 300 of microelectronic assembly 100, in particular, a region around conductive vias 108A and 108B of FIG. 2B during an early stage of manufacture. A support structure 302 represents various buildup layers and or other features of package substrate 102 that are irrelevant to the operations described further and are therefore not shown in detail. Support structure 302 may comprise, by way of example and not as a limitation, the structure up to the surface of organic dielectric material 110 proximate to surface 118 of package substrate 102. In yet another example, structure 302 may comprise, by way of example and not as a limitation, the structure including a portion of organic dielectric material 104 over organic dielectric material 110. Other such configurations are possible within the broad scope of the embodiments. Of relevance is merely that organic dielectric material 104 shown in FIG. 3A over support structure 302 represents any one layer 202 configured to include one or more conductive vias 108 rather than conductive traces 106 of package substrate 102. A seed layer 303 of copper or other metallic materials may be present over organic dielectric material 104, for example, to enhance adhesion of copper of conductive trace 106 in a subsequent process.

A layer of photoresist 304 of approximately 10 micrometer thickness may be deposited over seed layer 303. In various embodiments, photoresist 304 may comprise an organic polymeric material. Photoresist 304 may be exposed to three different light energy levels to generate corresponding portions 306, 308 and 310 according to a desired pattern using a single mask based on the same fiducials. Depending on whether photoresist 304 is a positive photoresist or negative photoresist, portion 306 corresponds to a region which is not removed in a subsequent processing by any solvent; portion 308 corresponds to a region that requires more than one solvent step for removal; and portion 310 corresponds to a region that is removable by a solvent in subsequent processing. Portion 310 corresponds to a pattern for a hardmask, outlined by a profile of conductive trace 106, and portion 308 corresponds to a pattern and location for corresponding conductive via 108A.

With positive photoresists, ultraviolet (UV) light strategically hits photoresist 304 in areas that are intended to be removed, i.e., in regions other than portion 306. When photoresist 304 is exposed to the UV light, the chemical structure changes and becomes more soluble in a photoresist developer. These exposed areas are then washed away with the photoresist developer solvent, leaving the underlying material. Using greyscale exposure with different light energy levels, portion 308 is partially polymerized under a lower dose of the UV light and requires more time for dissolving under the action of a solvent than portion 310, which received a higher dose of the UV light. With negative photoresists, exposure to UV light causes the chemical structure of photoresist 304 to polymerize. As a result, the UV exposed negative photoresist, such as portion 306, remains on the surface while the photoresist developer solution removes the areas that are unexposed. Using greyscale exposure with different light energy levels, portion 308 is partially polymerized under a higher dose of the UV light and requires more time for dissolving under the action of a solvent than portion 310, which received a lower dose (or none at all) of the UV light.

FIG. 3B shows a portion 310 subsequent to removal of portion 310 of photoresist 304 to generate a trench in which a hardmask 316 is deposited. Hardmask 316 may comprise a metallic material, such as copper, titanium nitride, or tantalum nitride in some embodiments. In other embodiments, hardmask 316 may comprise non-metallic materials, such as silicon dioxide, silicon carbide, etc. The choice of material for hardmask 316 may depend on the type of plasma used for dry etching and other factors beyond the scope of the present disclosure.

FIG. 3C shows a portion 320 subsequent to removal of portion 308 of photoresist 304 to generate a trench 322.

FIG. 3D shows a portion 325 subsequent to removal of seed layer 303 in the region of trench 322 to expose a surface 326 of organic dielectric material 104.

FIG. 3E shows a portion 330 subsequent to dry etching using a plasma to extend trench 322 into organic dielectric material 104. Thus, plasma is used to remove organic dielectric material 104 exposed by hardmask 316. The dry etching process results in orthogonal walls of trench 322 in organic dielectric material 104, as also an undercut 332 under seed layer 303.

FIG. 3F shows a portion 335 subsequent to removing hardmask 316, for example, by wet etching or an ablative process. In some embodiments where the material of hardmask 316 is the same as seed layer 303, the latter may be removed during this process as well.

FIG. 3G shows a portion 340 subsequent to depositing (e.g., electroplating) conductive material of conductive trace 106 and conductive via 108 in the trenches exposed by the previous operations described in reference to FIG. 3F. The operation follows a dual damascene technique with trenches (corresponding to traces) and vias (hence dual or twice used) formed first, and into which copper is electroplated in a single operation. Because conductive trace 106 and conductive via 108 are formed in a single electroplating operation, they form a unitary structure undivided by any seam, interface, or other material (except for some of seed layer 303 in some embodiments). Further, because a profile or outline of conductive trace 106 was used to generate hardmask 316 for the dry etching operation described in reference to FIG. 3E, conductive via 108 is self-aligned with conductive trace 106, with zero-misalignment. Still further, undercut 332 created during the dry etching process causes protrusion 212. A surface 342 of conductive trace 106 may be planarized in a planarizing operation, such as chemical mechanical polishing (CMP).

FIG. 3H shows a portion 345 subsequent to stripping away any remaining portion 306 of photoresist 304, etching away seed layer 303 around conductive trace 106, and depositing organic dielectric material 104 around and over conductive trace 106. In some embodiments, the operations may stop here, for example, where conductive trace 106 is proximate to surface 118 (or 120) of package substrate 102. In other embodiments, where conductive trace 106 is farther from surface 118 (or 120) with additional layers of organic dielectric material, the operations may proceed further.

FIG. 3I shows a portion 350 subsequent to depositing seed layer 303 of copper (or other suitable metallic material) over organic dielectric material 104 of portion 345. A layer of photoresist 304 is deposited over seed layer 303 and subjected to greyscale UV light exposure to generate different portions 306, 308 and 310 as described previously. Portion 310 corresponds to a pattern for a hardmask outlined by a profile of another conductive trace 106B (whereas the previously labeled conductive trace 106 is now labeled as 106A in the figure to distinguish it from conductive trace 106B), and portion 308 corresponds to a pattern and location for corresponding conductive via 108B.

Because the pattern used to generate portions 306, 308 and 310 are independent of conductive trace 106A, in that the alignment of the pattern is based on fiducials and other markers independent of the process of forming conductive trace 106A, there is a non-zero likelihood of misalignment between the location of portion 308 and a desired location of conductive via 108B, leading to a potential for EPE 213 in excess of 0.1 micrometers. Further, because staggered via locations may be desired in some embodiments, the location of portion 308 may be displaced along the length of conductive trace 106A from conductive trace 108A.

FIG. 3J shows a portion 355 subsequent to removing portion 310 of photoresist 304 and depositing hardmask 316 in the resulting trench.

FIG. 3K shows a portion 360 subsequent to removing portion 308 of photoresist 304 and seed layer 303 in resulting trench 322 to expose a surface of underlying organic dielectric material 104.

FIG. 3L shows a portion 365 subsequent to extending trench 322 into organic dielectric material 104 by dry etching using plasma. An undercut is formed under seed layer 303.

FIG. 3M shows a portion 370 subsequent to removing hardmask 316.

FIG. 3N shows a portion 375 subsequent to depositing conductive material of conductive trace 106B and conductive via 108B in the resulting space. The surface of conductive trace 106B and photoresist 304 is planarized suitably.

FIG. 3O shows a portion 380 subsequent to removing photoresist 304, stripping seed layer 303 and depositing additional organic dielectric material around conductive trace 106B.

FIG. 3P shows a simplified plan view of portion 380. Conductive traces 106A and 106B may not be aligned because of a likelihood of misalignment during the operations as described in FIG. 3I. Conductive via 108B may be self-aligned with conductive trace 106B, but not with conductive trace 106A for the reasons discussed therein. The operations as described herein may be repeated any number of times to generate package substrate 102 with staggered self-aligned vias.

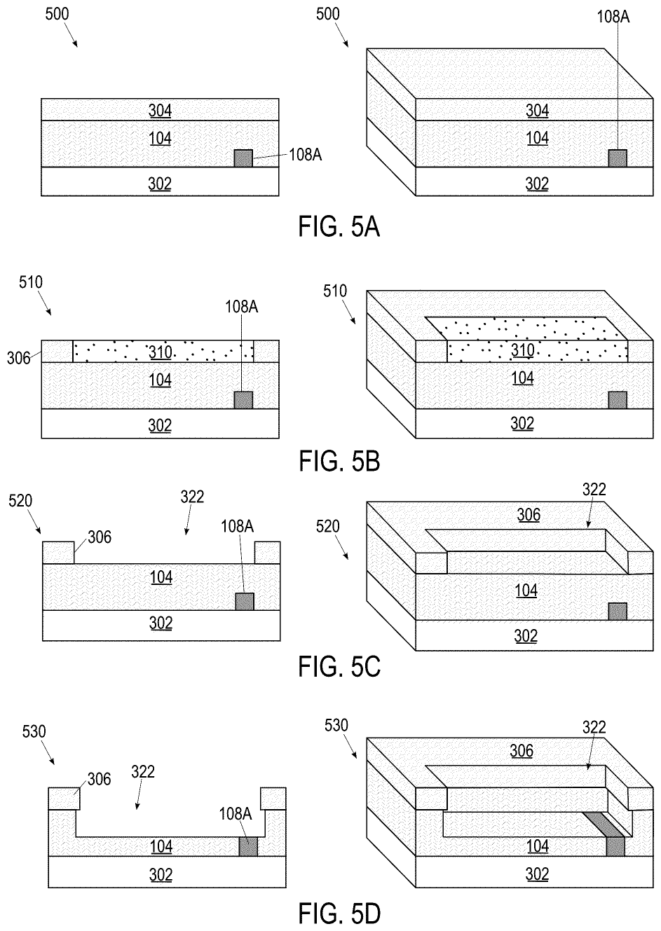

FIG. 4 is a simplified cross-sectional view of a portion 400 of package substrate 102. In some embodiments, wherein conductive trace 106 is proximate to surface 118 (or surface 120) of package substrate 102, after the operations as described in reference to FIG. 3H, conductive via 108B may be formed by laser drilling and electroplating rather than photolithography processes. In such embodiments too, conductive via 108B may have EPE exceeding 0.1 micrometers because of the likelihood of misalignment in the laser drill pattern relative to conductive trace 106, which is buried underneath organic dielectric material 104. In such embodiments, sidewalls of conductive via 108B may neither have protrusions, nor any scalloped edges, depending on the configuration of the laser used to generate the trench for conductive via 108B.

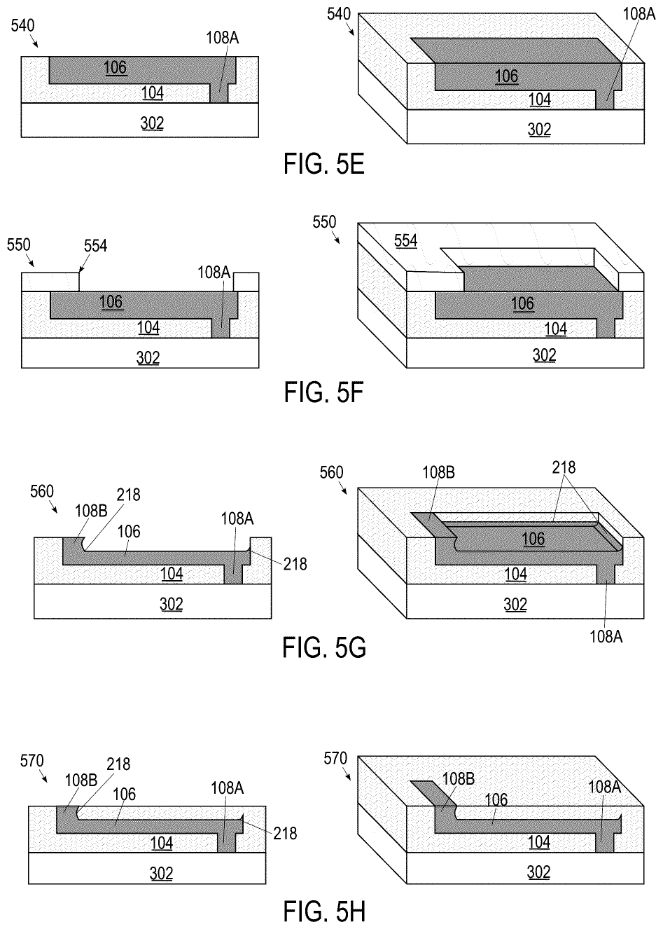

FIGS. 5A-5H are simplified cross-sectional views of various stages of manufacture of microelectronic assembly 100 according to some embodiments of the present disclosure. FIG. 5A shows a portion 500 of microelectronic assembly 100, in particular, a region around conductive vias 108A and 108B of FIG. 2B during an early stage of manufacture. A support structure 302 represents various buildup layers and or other features of package substrate 102 that are irrelevant to the operations described further and are therefore not shown in detail. Support structure 302 may comprise, by way of example and not as a limitation, the structure up to the surface of organic dielectric material 110 proximate to surface 118 of package substrate 102. In yet another example, structure 302 may comprise, by way of example and not as a limitation, the structure including a portion of organic dielectric material 104 over organic dielectric material 110. Other such configurations are possible within the broad scope of the embodiments. Of relevance is merely that organic dielectric material 104 shown in FIG. 5A over support structure 302 represents any two layers 202 configured to include one or more conductive vias 108 (e.g., 108A) on the bottom and conductive traces 106 on the top. A layer of photoresist 304 may be deposited over organic dielectric material 104.

FIG. 5B is a simplified cross-sectional view of a portion 510 subsequent to exposing photoresist 304 to UV light and forming portions 306 and 310. Portion 310 may correspond to a profile or outline of conductive trace 106 and portion 306 corresponds to other areas. Note that because the pattern is generated independently of conductive via 108A, portion 310 may not align exactly with a desired location of conductive trace 106, resulting in an EPE that exceeds 0.1 micrometers.

FIG. 5C is a simplified cross-sectional view of a portion 520 subsequent to removing portion 310 of photoresist 304 and forming a trench 322.

FIG. 5D is a simplified cross-sectional view of a portion 530 subsequent to extending trench 322 into organic dielectric material 104 by dry etching using plasma. Trench 322 may be extended until the surface of conductive via 108A is visible in trench 322.

FIG. 5E is a simplified cross-sectional view of a portion 540 subsequent to depositing the conductive material of conductive trace 106 in trench 322 and removing remaining portion 306 of photoresist 304.

FIG. 5F is a simplified cross-sectional view of a portion 550 subsequent to depositing hardmask 554 over portion 540 and patterning to reveal a first portion of conductive trace 106 whereas a second portion corresponding to conductive trace 108B remained unexposed. Note in that the material for hardmask 554 is different from the material of conductive trace 106.

FIG. 5G is a simplified cross-sectional view of a portion 560 subsequent to wet etching, removing conductive material in the exposed portion of conductive trace 106. The wet etching leads to scalloped (i.e., concave) profiles 218 of all surfaces along the perimeter of the exposed portion, including sidewalls of conductive via 108B and some surfaces of conductive trace 106. Further, the sidewalls of conductive via 108B orthogonal to the scalloped sidewall is aligned exactly with respective proximate surfaces of conductive trace 106. In embodiments where conductive via 108B is located along a terminating edge of conductive trace 106, the sidewall of conductive via 108B opposite to the scalloped sidewall may also be aligned exactly with the proximate surface of conductive trace 106.

FIG. 5H is a simplified cross-sectional view of a portion 570 subsequent to depositing organic dielectric material in the spaces created by the wet etching process to complete forming staggered conductive vias 108A and 108B, conductive via 108B being self-aligned with conductive trace 106. The operations as described by FIGS. 5A-5H follow the dual damascene technique with trenches and vias formed before copper is electroplated simultaneously into both.

Although FIGS. 3-5 illustrate various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 3-5 may be modified in accordance with the present disclosure to fabricate others of microelectronic assembly 100 disclosed herein. Although various operations are illustrated in FIGS. 3-5 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 3-5 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in the figure may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

Example Devices and Components

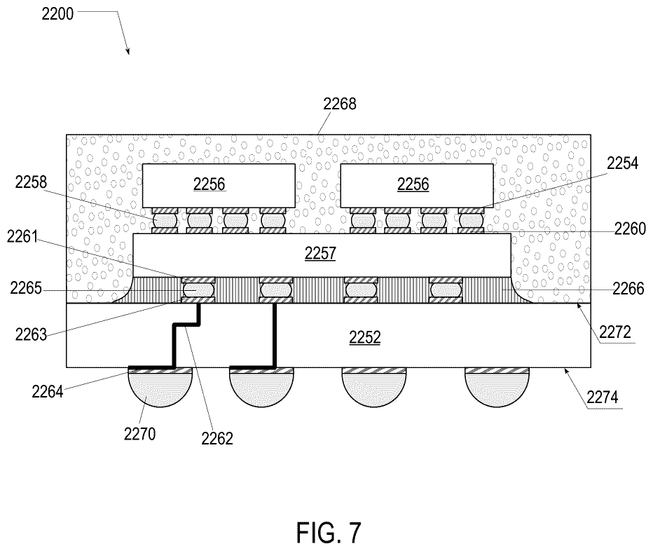

The packages disclosed herein, e.g., any of the embodiments shown in FIGS. 1-6 or any further embodiments described herein, may be included in any suitable electronic component. FIGS. 7-9 illustrate various examples of packages, assemblies, and devices that may be used with or include any of the IC packages as disclosed herein.

FIG. 7 is a side, cross-sectional view of an example IC package 2200 that may include IC packages in accordance with any of the embodiments disclosed herein. In some embodiments, the IC package 2200 may be a SIP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

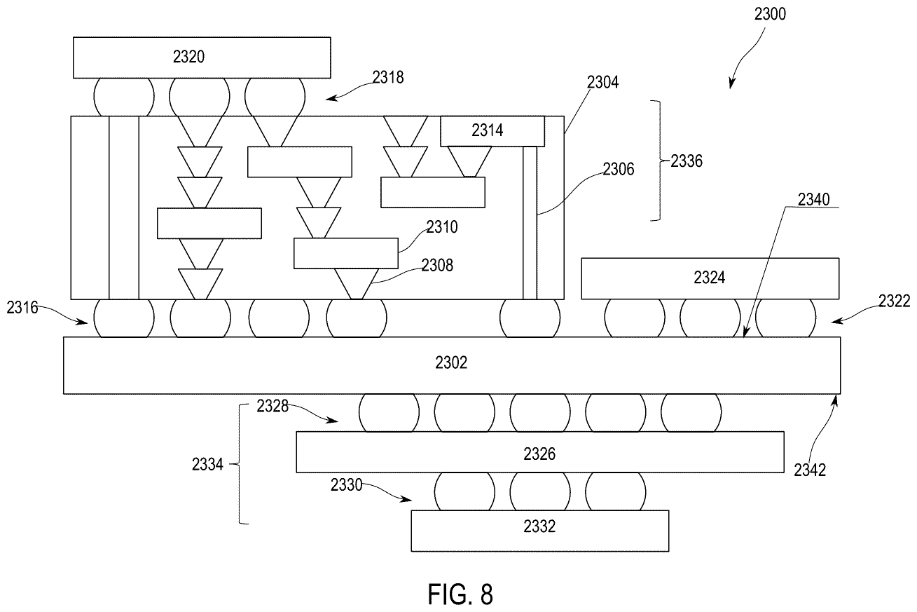

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 8.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 8 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 7.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 7. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

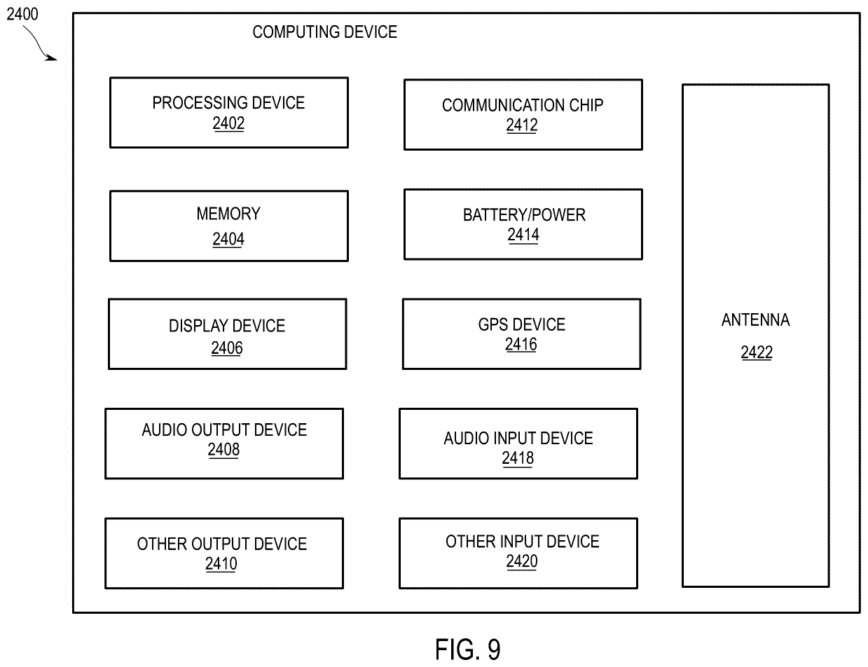

FIG. 9 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 7). In yet another example, any one or more of the components of computing device 2400 may include an IC device assembly 2300 (e.g., as shown in FIG. 8).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### SELECT EXAMPLES

Example 1 provides a microelectronic assembly (e.g., 100, FIG. 1), comprising: a package substrate (e.g., 102) comprising a plurality of layers of organic dielectric material (e.g., 104) and conductive traces (e.g., 106) alternating with conductive vias (e.g., 108) in alternate layers of the organic dielectric material; and a plurality of IC dies (e.g., 116) coupled to a first side (e.g., 118) of the package substrate by interconnects (e.g., 122), wherein: the plurality of layers of the organic dielectric material comprises at least a first layer (e.g., 202(1)) having a conductive via (e.g., 108A) and a second layer (e.g., 202(2)) having a conductive trace (e.g., 106) in contact with the conductive via, the second layer is not coplanar with the first layer, sidewalls (e.g., 210) of the conductive via are orthogonal to the conductive trace, and two opposing sidewalls (e.g., 210A, 210B) of the conductive via separated by a width of the conductive via protrude from respectively proximate edges (e.g., 211A, 2118) of the conductive trace by a protrusion (e.g., 212) that is at least ten times less than the width of the conductive via.
Example 2 provides the microelectronic assembly of example 1, wherein another sidewall (e.g., 210C) of the conductive via orthogonal to the two opposing sidewalls protrudes from a respectively proximate edge (e.g., 211C) of the conductive trace by the protrusion.
Example 3 provides the microelectronic assembly of any one of examples 1-2, wherein the first layer is under the second layer.
Example 4 provides the microelectronic assembly of any one of examples 1-3, wherein a first centerline (e.g., 206A) of the conductive via is aligned with respect to a second centerline (e.g., 204) of the conductive trace.
Example 5 provides the microelectronic assembly of example 4, wherein: the conductive via is a first conductive via, the package substrate comprises a second conductive via in a third layer (e.g., 202(3)) of the organic dielectric material, the first layer, the second layer and the third layer are not coplanar, the second conductive via has at least substantially same width as the first conductive via, the conductive trace is in contact with the second conductive via, the second centerline of the conductive trace is not aligned with a third centerline of the second conductive via.
Example 6 provides the microelectronic assembly of example 4, wherein: the conductive via is a first conductive via, the package substrate comprises a second conductive via in a third layer (e.g., 202(3)) of the organic dielectric material, the first layer, the second layer and the third layer are not coplanar, the second conductive via has at least substantially same width as the first conductive via, the conductive trace is in contact with the second conductive via, and at least one sidewall of the second conductive via has concave profiles.
Example 7 provides the microelectronic assembly of example 6, wherein the second centerline of the conductive trace is aligned with a third centerline of the second conductive via.
Example 8 provides the microelectronic assembly of example 6, wherein edges of the conductive trace have concave profiles.
Example 9 provides the microelectronic assembly of any one of examples 1-8, wherein the organic dielectric material comprises a polyimide or epoxy-based buildup film.
Example 10 provides the microelectronic assembly of any one of examples 1-9, wherein: the package substrate further comprises a bridge die, and conductive pathways through the bridge die conductively couples at least two of the plurality of IC dies on the package substrate.
Example 11 provides the microelectronic assembly of example 10, wherein: the organic dielectric material is a first organic dielectric material, the bridge die is surrounded by a second organic dielectric material, the first organic dielectric material is between the second organic dielectric material and the plurality of IC dies, and the first dielectric material is different from the second organic dielectric material.
Example 12 provides the microelectronic assembly of example 11, wherein: the package substrate further comprises bond-pads on a side of the second organic dielectric material opposite to the first organic dielectric material, and TDVs in the second organic dielectric material conductively couple the conductive traces in the first organic dielectric material with the bond-pads.
Example 13 provides the microelectronic assembly of example 12, wherein: the second dielectric material is between layers of the first organic dielectric material, and the bond-pads are in another layer of the first organic dielectric material.
Example 14 provides the microelectronic assembly of any one of examples 12-13, wherein: the bond-pads are configured for mid-level interconnects, and the package substrate is configured to be coupled to a substrate by the mid-level interconnects.
Example 15 provides the microelectronic assembly of any one of examples 12-13, wherein: the bond-pads are configured for second-level interconnects, and the package substrate is configured to be coupled to a motherboard by the second-level interconnects.
Example 16 provides the microelectronic assembly of any one of examples 1-15, wherein the conductive traces and the conductive vias comprise copper.
Example 17 provides a package substrate, comprising: a plurality of layers of organic dielectric material (e.g., 104); a conductive via (e.g., 108A) in a first layer (e.g., 202(1)) of the organic dielectric material; and a conductive trace (e.g., 106) in a second layer (e.g., 202(2)) of the organic dielectric material; wherein: the second layer is over the first layer, the conductive via is attached to a portion of the conductive trace, and an EPE of the conductive via on the conductive trace is less than 0.1 micrometers.
Example 18 provides the package substrate of example 17, wherein sidewalls of the conductive via protrude from respectively proximate edges of the portion of the conductive trace by a protrusion (e.g., 212) that is at least ten times less than a width of the conductive via.
Example 19 provides the package substrate of any one of examples 17-18, wherein sidewalls of the conductive via are orthogonal to the portion of the conductive trace.
Example 20 provides the package substrate of any one of examples 17-19, wherein a first width of the conductive via is a sum of the second width of the portion of the conductive trace and twice the protrusion.
Example 21 provides the package substrate of any one of examples 17-20, wherein the portion of the conductive trace and the conductive via form a homogeneous unitary structure without any intervening interfaces, seams, or materials.
Example 22 provides the package substrate of any one of examples 17-21, wherein centerlines of the conductive via and the portion of the conductive trace are mutually aligned.
Example 23 provides the package substrate of any one of examples 17-22, wherein: the conductive via is a first conductive via, the portion of the conductive trace is a first portion, the package substrate further comprises a second conductive via in a third layer of the organic dielectric material, the third layer is over the second layer, the second conductive via is attached to a second portion of the conductive trace, and centerlines of the second conductive via and the second portion of the conductive trace are not mutually aligned.
Example 24 provides the package substrate of example 23, wherein: the conductive trace is a first conductive trace, the package substrate further comprises a second conductive trace in a fourth layer, the fourth layer is over the third layer, the second conductive via is attached to a third portion of the second conductive trace, and centerlines of the second conductive via and the third portion of the second conductive trace are mutually aligned.
Example 25 provides the package substrate of any one of examples 23-24, wherein: the conductive trace is proximate to a surface of the package substrate, and the second conductive via is generated by laser drilling through the organic dielectric material.
Example 26 provides the package substrate of any one of examples 17-25, wherein the organic dielectric material is at least one of a polyimide or an epoxy-based buildup film.
Example 27 provides the package substrate of any one of examples 17-26, wherein an EPE (e.g., 1802) of the conductive via relative to the conductive trace is less than 0.1 micrometers.
Example 28 provides a package substrate, comprising: a plurality of layers of organic dielectric material (e.g., 104); a conductive via (e.g., 108A) in a first layer (e.g., 202(1)) of the organic dielectric material; and a conductive trace (e.g., 106) in a second layer (e.g., 202(2)) of the organic dielectric material; wherein: the first layer is over the second layer, the conductive via is attached to a portion of the conductive trace, at least one sidewall (e.g., 210) of the conductive via has a scalloped profile, and centerlines of the conductive via and the portion of the conductive trace are mutually aligned.
Example 29 provides the package substrate of example 28, wherein: the at least one sidewall is a first sidewall, the conductive via is located at an edge (e.g., 211) of the conductive trace, at least a second sidewall, a third sidewall and a fourth sidewall of the conductive via align exactly with corresponding edges of the conductive trace, the second sidewall is opposite to the first sidewall, and the third sidewall and the fourth sidewall are mutually opposite and orthogonal to the second sidewall and the first sidewall.
Example 30 provides the package substrate of any one of examples 28-29, wherein: the conductive via is not located at an edge of the conductive trace, and all sidewalls of the conductive via have scalloped profiles.
Example 31 provides the package substrate of any one of examples 28-30, wherein edges of the conductive trace have scalloped profiles.
Example 32 provides the package substrate of any one of examples 28-31, wherein the conductive trace and the conductive via form a homogeneous unitary structure without any intervening interfaces, seams, or materials.
Example 33 provides the package substrate of any one of examples 28-32, wherein: the conductive via is a first conductive via, the portion of the conductive trace is a first portion, the package substrate further comprises a second conductive via in a third layer of the organic dielectric material, the third layer is under the second layer, the second conductive via is attached to a second portion of the conductive trace, and centerlines of the second conductive via and the second portion of the conductive trace are not mutually aligned.
Example 34 provides the package substrate of any one of examples 28-33, wherein the organic dielectric material is at least one of a polyimide or an epoxy-based buildup film.
Example 35 provides the package substrate of any one of examples 28-34, wherein an EPE (e.g., 1802) of the conductive via relative to the conductive trace is less than 0.1 micrometers.
Example 36 provides the package substrate of any one of examples 28-35, wherein the conductive trace and the conductive via comprise copper.
Example 37 provides a method, comprising: providing a support structure comprising a seed layer of conductive material over an organic dielectric material; depositing a first layer of photoresist over the seed layer; forming a first trench in the photoresist, the first trench corresponding to a portion of a conductive trace; forming a hard mask in the first trench; forming a second trench in the organic dielectric material, the second trend corresponding to a conductive via; depositing conductive material in the second trench to form the conductive trace and connected via; stripping any remaining photoresist and the seed layer; and depositing the organic dielectric material around and over the conductive trace.
Example 38 provides the method of example 37, wherein forming the first trench in the organic dielectric material comprises: exposing a first portion of the photoresist to a first light energy level; exposing a second portion of the photoresist to a second light energy level; and removing the first portion of the photoresist that was exposed, wherein the first portion of the photoresist corresponds to the first trench and the second portion of the photoresist corresponds to the second trench.
Example 39 provides the method of example 38, wherein forming the second trench in the organic dielectric material comprises: exposing the second portion of the photoresist to the first light energy level; removing the second portion of the photoresist that was exposed to the first light energy level such that a third portion of the seed layer is exposed; wet etching the third portion of the seed layer such that a surface (e.g., 326) of a fourth portion of the organic dielectric material is exposed; and removing the fourth portion of the organic dielectric material by dry etching.
Example 40 provides the method of example 39, wherein a first footprint of the surface of a fourth portion of the organic dielectric material is smaller than a second footprint of the second trench such that an undercut (e.g., 332) is generated under the seed layer during the dry etching.
Example 41 provides the method of any one of examples 37-40, further comprising, before stripping any remaining photoresist and the seed layer, planarizing a surface (e.g., 342) of the photoresist and the conductive material corresponding to the conductive trace.
Example 42 provides the method of any one of examples 37-41, wherein the organic dielectric material is at least one of a polyimide and an epoxy-based buildup film material.
Example 43 provides the method of any one of examples 37-42, wherein the conductive material is copper.
Example 44 provides the method of any one of examples 37-43, wherein a material of the hard mask is different from the conductive material.
Example 45 provides the method of any one of examples 37-44, wherein a material of the hard mask is same as the conductive material.
Example 46 provides the method of any one of examples 37-45, wherein: a first centerline of the conductive trace is aligned with a second centerline of the conductive via.
Example 47 provides a method, comprising: providing a support structure comprising an organic dielectric material; depositing a layer of photoresist over the organic dielectric material; forming a trench in the organic dielectric material; depositing conductive material in the trench to form a conductive trace; wet etching the conductive trace to form a conductive via having at least one scalloped surface and scalloped edges along a periphery of the conductive trace; and depositing the organic dielectric material over the conductive trace.
Example 48 provides the method of example 47, further comprising: after depositing the conductive material and before wet etching, removing the layer of photoresist.
Example 49 provides the method of any one of examples 47-48, wherein forming the trench in the organic dielectric material comprises: exposing a first portion of the photoresist to light according to a pattern of a conductive trace; removing the first portion of the photoresist such that a second portion of the organic dielectric material is exposed; removing the second portion of the organic dielectric material by dry etching to form the trench.
Example 50 provides the method of any one of examples 47-49, wherein wet etching the conductive trace comprises: depositing a hard mask over the conductive trace and the organic dielectric material; and patterning the hard mask to expose a third portion of the conductive trace, wherein the third portion of the conductive trace does not include the conductive via.
Example 51 provides the method of example 50, wherein a material of the hard mask is different from the conductive material.
Example 52 provides the method of any one of examples 47-51, wherein the organic dielectric material is at least one of a polyimide and an epoxy-based buildup film material.
Example 53 provides the method of any one of examples 47-52, wherein the conductive material is copper.
Example 54 provides the method of any one of examples 47-53, wherein: a first centerline of the conductive trace is aligned with a second centerline of the conductive via.
Example 55 provides the method of example 54, wherein: the conductive via is a first conductive via, the support structure comprises a second conductive via, the first centerline of the conductive trace is not aligned with a third centerline of the second conductive via.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a package substrate comprising a plurality of layers of organic dielectric material and conductive traces alternating with conductive vias in alternate layers of the organic dielectric material; and
a plurality of integrated circuit (IC) dies coupled to a first side of the package substrate by interconnects,
wherein:
the plurality of layers of the organic dielectric material comprises at least a first layer having a conductive via and a second layer having a conductive trace in contact with the conductive via,
the second layer is not coplanar with the first layer,
sidewalls of the conductive via are orthogonal to the conductive trace, and
two opposing sidewalls of the conductive via separated by a width of the conductive via protrude from respectively proximate edges of the conductive trace by a protrusion that is at least ten times less than the width of the conductive via.

2. The microelectronic assembly of claim 1, wherein another sidewall of the conductive via orthogonal to the two opposing sidewalls protrudes from a respectively proximate edge of the conductive trace by the protrusion.

3. The microelectronic assembly of claim 1, wherein the first layer is under the second layer.

4. The microelectronic assembly of claim 1, wherein a first centerline of the conductive via is aligned with respect to a second centerline of the conductive trace.

5. The microelectronic assembly of claim 4, wherein:
the conductive via is a first conductive via,
the package substrate comprises a second conductive via in a third layer of the organic dielectric material,
the first layer, the second layer and the third layer are not coplanar,
the second conductive via has at least substantially same width as the first conductive via,
the conductive trace is in contact with the second conductive via,
the second centerline of the conductive trace is not aligned with a third centerline of the second conductive via.

6. The microelectronic assembly of claim 4, wherein:
the conductive via is a first conductive via,
the package substrate comprises a second conductive via in a third layer of the organic dielectric material,
the first layer, the second layer and the third layer are not coplanar,
the second conductive via has at least substantially same width as the first conductive via,
the conductive trace is in contact with the second conductive via, and
at least one sidewall of the second conductive via has concave profiles.

7. The microelectronic assembly of claim 1, wherein:
the package substrate further comprises a bridge die, and
conductive pathways through the bridge die conductively couples at least two of the plurality of IC dies on the package substrate.

8. A package substrate, comprising:
a plurality of layers of organic dielectric material;
a conductive via in a first layer of the organic dielectric material; and
a conductive trace in a second layer of the organic dielectric material;
wherein:
the second layer is over the first layer,
the conductive via is attached to a portion of the conductive trace, and
an edge placement error (EPE) of the conductive via on the conductive trace is less than 0.1 micrometers.

9. The package substrate of claim 8, wherein sidewalls of the conductive via protrude from respectively proximate edges of the portion of the conductive trace by a protrusion that is at least ten times less than a width of the conductive via.

10. The package substrate of claim 8, wherein sidewalls of the conductive via are orthogonal to the portion of the conductive trace.

11. The package substrate of claim 8, wherein centerlines of the conductive via and the portion of the conductive trace are mutually aligned.

12. The package substrate of claim 8, wherein:
the conductive via is a first conductive via,
the portion of the conductive trace is a first portion,
the package substrate further comprises a second conductive via in a third layer of the organic dielectric material,
the third layer is over the second layer,
the second conductive via is attached to a second portion of the conductive trace, and
centerlines of the second conductive via and the second portion of the conductive trace are not mutually aligned.

13. The package substrate of claim 12, wherein:
the conductive trace is proximate to a surface of the package substrate, and
the second conductive via is generated by laser drilling through the organic dielectric material.

14. The package substrate of claim 8, wherein the organic dielectric material is at least one of a polyimide or an epoxy-based buildup film.

15. A package substrate, comprising:
a plurality of layers of organic dielectric material;
a conductive via in a first layer of the organic dielectric material; and
a conductive trace in a second layer of the organic dielectric material;
wherein:
the first layer is over the second layer,
the conductive via is attached to a portion of the conductive trace,
at least one sidewall of the conductive via has a scalloped profile, and
centerlines of the conductive via and the portion of the conductive trace are mutually aligned.

16. The package substrate of claim 15, wherein:
the at least one sidewall is a first sidewall,
the conductive via is located at an edge of the conductive trace,
at least a second sidewall, a third sidewall and a fourth sidewall of the conductive via align exactly with corresponding edges of the conductive trace,
the second sidewall is opposite to the first sidewall, and
the third sidewall and the fourth sidewall are mutually opposite and orthogonal to the second sidewall and the first sidewall.

17. The package substrate of claim 15, wherein:
the conductive via is not located at an edge of the conductive trace, and
all sidewalls of the conductive via have scalloped profiles.

18. The package substrate of claim 15, wherein edges of the conductive trace have scalloped profiles.

19. The package substrate of claim 15, wherein:
the conductive via is a first conductive via,
the portion of the conductive trace is a first portion,
the package substrate further comprises a second conductive via in a third layer of the organic dielectric material,
the third layer is under the second layer,
the second conductive via is attached to a second portion of the conductive trace, and
centerlines of the second conductive via and the second portion of the conductive trace are not mutually aligned.

20. The package substrate of claim 15, wherein the organic dielectric material is at least one of a polyimide or an epoxy-based buildup film.
